(19) United States
(12) Patent Application Publication
(10) Pub. No.: US 2014/0133253 A1
(43) Pub. Date: May 15, 2014

(54) System and Method for Memory Testing

(71) Applicant: Taiwan Semiconductor Manufacturing Company, Ltd., (US)

(72) Inventors: Chao Kai Chuang, Hsinchu City (TW); Ching-Wei Wu, Caotun Town (TW)

(73) Assignee: Taiwan Semiconductor Manufacturing Company, Ltd., Hsin-Chu (TW)

(21) Appl. No.: 13/675,823

(22) Filed: Nov. 13, 2012

(51) Int. Cl. G11C 29/12

(52) U.S. Cl. CPC G11C 29/12
USPC 365/201

(57) ABSTRACT

An embodiment method of testing a memory includes writing a first logic state to a first cell in a first clock cycle and reading the first logic state in the first cell in a second clock cycle in a first phase, and reading the first logic state in the first cell and writing a second logic state to the first cell in the first clock cycle and reading the second logic state in the first cell in the second clock cycle in a second phase. As such, a concurrent read/write operation is performed at the same time and for the same memory bit (i.e., the first cell).

### BACKGROUND

Built-in self-test (BIST) units are now commonly incorporated into memory chips and other integrated circuits to test their functionality and reliability. For example, a BIST unit incorporated into a particular memory module operates by writing and reading various data patterns to and from the memory module to detect any possible memory faults. By comparing the data written and the data subsequently returned from the memory module, the BIST unit is able to determine whether any memory cell of the memory module is faulty.

The integrated BIST unit typically generates a variety of predetermined test patterns and asserts or de-asserts an output signal based on the results of the memory test. A variety of algorithms generating test patterns of all zeros, all ones, or alternating zeros and ones may be written throughout the memory cells in an effort to detect memory faults.

Unfortunately, traditional algorithms used for memory testing have drawbacks. By way of example, a traditional BIST test algorithm for a six transistor (6T) 2-port register file (2PRF) SRAM does not support a concurrent read/write operation feature. Indeed, the traditional BIST test algorithm only tests and verifies the write operation of a concurrent read/write. As such, the read operation of the concurrent read/write is not verified.

### BRIEF DESCRIPTION OF THE DRAWINGS

For a more complete understanding of the present disclosure, and the advantages thereof, reference is now made to the following descriptions taken in conjunction with the accompanying drawings, in which:

FIG. 1 illustrates a typical process of testing a static random access memory (SRAM) with a built-in self-test (BIST) tool;

FIG. 2 illustrates an embodiment integrated circuit having a SRAM and a BIST tool;

FIG. 3 illustrates an embodiment table highlighting concurrent read and write functions offered by the BIST tool of FIG. 2;

FIG. 4 illustrates an embodiment process of testing the SRAM of FIG. 2 with an embodiment BIST tool;

FIG. 5 illustrates a flow diagram for the typical process of FIG. 1;

FIG. 6 illustrates a flow diagram for the embodiment process of FIG. 4;

FIGS. 7a-7c collectively illustrate a first phase for the embodiment process of FIG. 4;

FIGS. 8a-8c collectively illustrate a second phase for the embodiment process of FIG. 4;

FIGS. 9a-9c collectively illustrate a third phase for the embodiment process of FIG. 4;

FIGS. 10a-10c collectively illustrate a fourth phase for the embodiment process of FIG. 4; and

FIG. 11 illustrates a chart comparing parameters of the typical process of FIG. 2 with the embodiment process of FIG. 4.

Corresponding numerals and symbols in the different figures generally refer to corresponding parts unless otherwise indicated. The figures are drawn to clearly illustrate the relevant aspects of the embodiments and are not necessarily drawn to scale.

### DETAILED DESCRIPTION OF ILLUSTRATIVE EMBODIMENTS

The making and using of the presently preferred embodiments are discussed in detail below. It should be appreciated, however, that the present disclosure provides many applicable inventive concepts that can be embodied in a wide variety of specific contexts. The specific embodiments discussed are merely illustrative and do not limit the scope of the disclosure.

The present disclosure will be described with respect to preferred embodiments in a specific context, namely a test algorithm used to test an SRAM on a chip. The concepts in the disclosure may also apply, however, to test algorithms used to test other types of memory operating on or with other semiconductor devices and circuits.

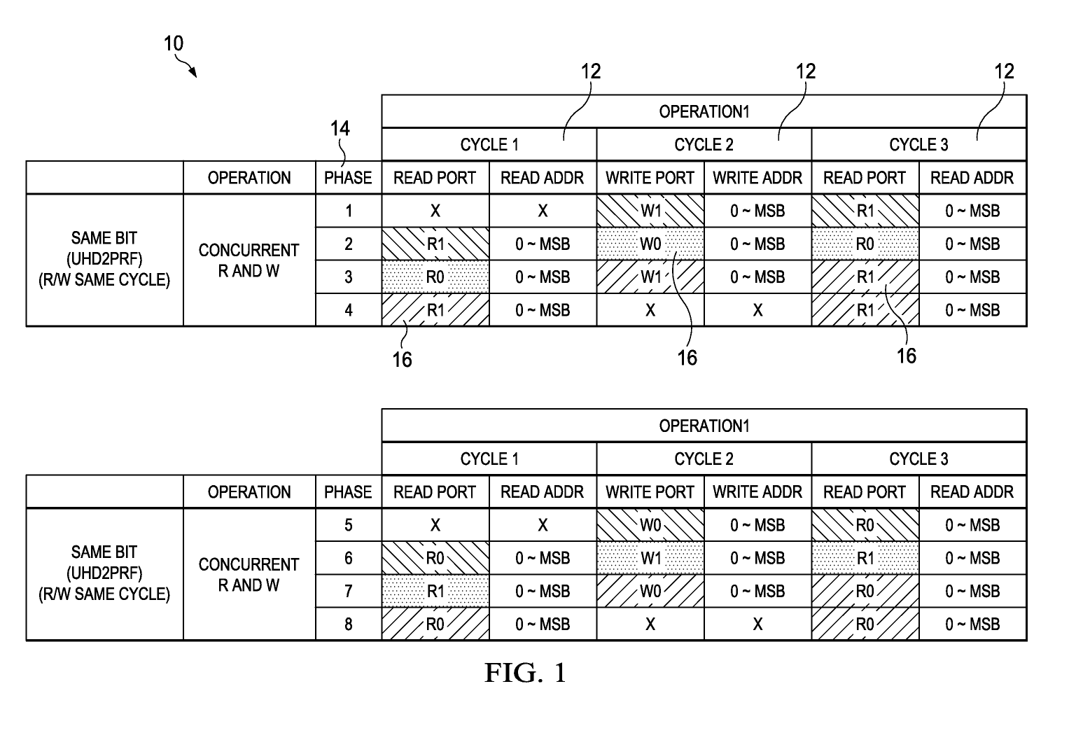

To provide context, a typical process 10 of testing a static random access memory (SRAM) with a conventional build-in self-test circuit (BIST) tool is graphically illustrated in FIG. 1. As shown in FIG. 1, the testing process 10 uses three clock cycles 12 (Cycles 1-3) per phase 14 (Phases 1-8) in order to test each cell 16 (i.e., bit) of the SRAM. By way of example, if the SRAM has four bits, the first cell is tested in the first phase using three clock cycles, then the second cell is tested in the first phase using three clock cycles, and so on until all four cells have been tested in the first phase. This pattern is generally repeated for each of phases 2-8.

Notably, during the typical testing process 10, either a first logical state such as a logic “1” or a second logical state such as a logic “0” is written to the cell or read from the cell being tested. As shown in FIG. 1, when the logic “1” is written it is represented as “W1” and when the logic “0” is written it is represented as “W0.” In contrast, when the logic “1” is read it is represented as “R1” and when the logic “0” is read it is represented as “R0.” When no action is performed during the particular clock cycle, an “X” is used.

As shown in FIG. 1, the logic states used in phases 5-8 of the typical testing process 10 are generally a mirror image or the opposite of the logic states used in phases 1-4. In other words, where the logic “1” is written and read in phases 1-4 in FIG. 1, the logic “0” is written and read in phases 5- 8. Likewise, where the logic “0” is written and read in phases 1-4 in FIG. 1, the logic “1” is written and read in phases 5- 8. As such, each cell or bit of the SRAM is tested using both the logic “1” and the logic “0” for the both read and the write operation.

Still referring to FIG. 1, the testing process 10 generally uses read and write addresses in a range from zero to the most significant bit (MSB). By way of example, if a 4-bit SRAM is being tested, addresses of zero to three (0, 1, 2, 3) are used for the read and write operations. If the SRAM includes additional bits, a similar addressing scheme may be used.

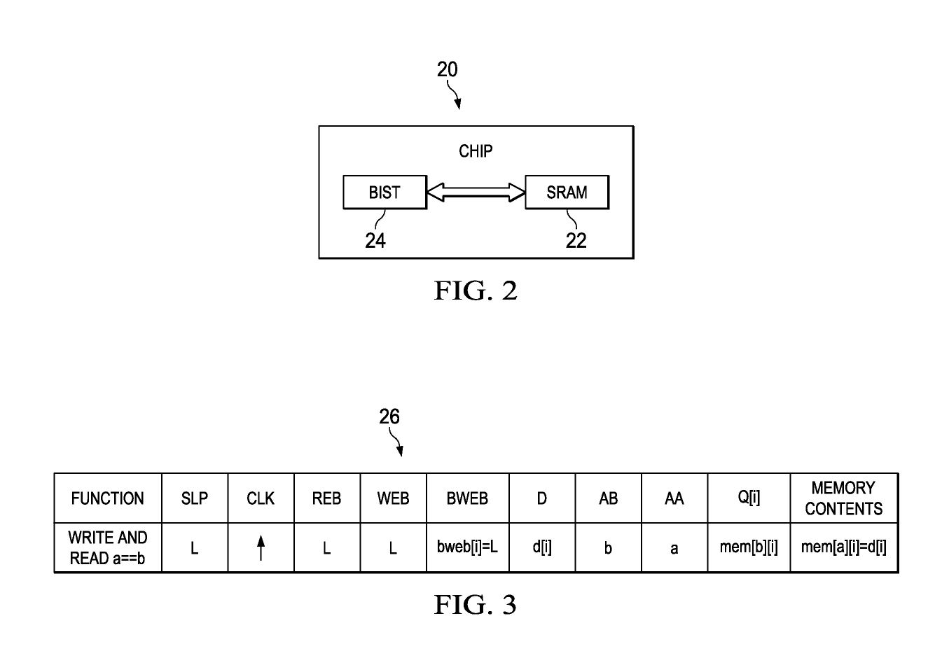

Referring now to FIG. 2, an embodiment integrated circuit 20 (i.e., chip, die, etc.) is illustrated. As shown, the integrated circuit (IC) 20 includes a memory 22 operably coupled to a test mechanism 24. In an embodiment, the memory 22 is a static random access memory (SRAM) 12 and the test mechanism 24 is a build-in self-test (BIST) tool. In an embodiment, the memory 12 is a multiple transistor (6T, 8T, etc.) 2-port register file (2PRF) ultra-high density (UHD) SRAM.

It should be recognized that in an embodiment the memory 22 of FIG. 2 may be other types of memory capable of providing data storage including, for example, synchronous dynamic random access memory (synchronous DRAM or SDRAM), double data rate (DDR) SDRAM, and so on. It should also be recognized that the integrated circuit 10 may contain a variety of other active and passive devices, circuits, and semiconductor components in addition to those shown.

As will be more fully explained below, the test mechanism 24 of FIG. 2 permits both read and write functions to occur at the same time for the same memory bit. A high level illustration of this functionality is shown through a table 26 of FIG. 3. As shown in the table 26 of FIG. 3, the write and read functions are performed concurrently (i.e., the Function is Write and Read a==b, the Q[i] is mem[b][i], and the Memory Contents is mem[a][i]=d[i]).

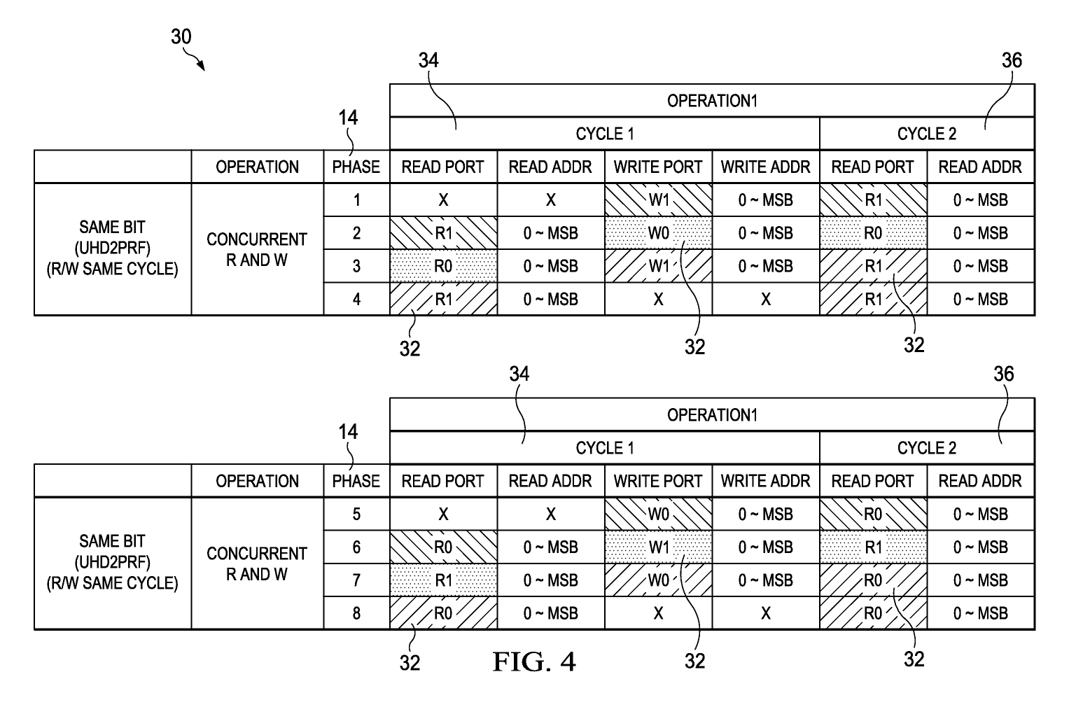

Referring now to FIG. 4, an embodiment process 30 of testing the memory 22 (e.g., SRAM) with the embodiment test mechanism 24 (e.g., BIST tool) of FIG. 2 is provided in additional detail. By way of example, FIG. 4 depicts the testing of a four-bit SRAM. Even so, memory devices having a different number of bits may be tested in the same manner. Notably, the embodiment test process 30 uses only two clock cycles instead of the three clock cycles shown in FIG. 1. In an embodiment, the test process 30 is an algorithm implemented by the test mechanism 24 of FIG. 2.

As shown in FIG. 4, when the test process 30 begins with the first phase 14 (i.e., Phase 1) nothing has been written to the any of the cells 32 in the memory 22 yet. Therefore, the read port and read address corresponding to a first clock cycle 34 (i.e., Cycle 1) are each denoted with an “X.” As the test process 30 continues, the first logic state is written (represented by “W1”) to the first cell in the first clock cycle 34 and the first logic state is read (represented by “R1”) in the first cell in a second clock cycle 36 (i.e., Cycle 2) in the first phase 14. The process of writing a logic “1” in the first clock cycle 34 and reading the logic “1” in the second clock cycle 36 is repeated in the first phase 14 for each of the other bits in the memory 22 (e.g., bits 2, 3, and 4 from a 4- bit SRAM) as denoted by the “0˜MSB” for the write address and the read address under the first clock cycle 34 and the second clock cycle 36.

In a second phase 14 (i.e., Phase 2) of the test process 30, the first logic state is read in the first cell (represented by “R1”) and the second logic state is written in the first cell (represented by “W0”) in the first clock cycle 34. In addition, the second logic state is read (represented by “R0”) in the first cell in the second clock cycle 36. The process of concurrently reading the logic “1” and writing the logic “0” in the first clock cycle 34 and then reading the logic “0” in the second clock cycle 36 is repeated in the second phase 14 for each of the other bits in the memory 22.

In a third phase 14 (i.e., Phase 3) of the test process 30, the second logic state is read in the first cell (represented by “R0”) and the first logic state is written in the first cell (represented by “W1”) in the first clock cycle 34. In addition, the first logic state is read (represented by “R1”) in the first cell in the second clock cycle 36. The process of concurrently reading the logic “1” and writing the logic “0” in the first clock 34 and then reading the logic “0” in the second clock cycle 36 is repeated in the second phase 14 for each of the other bits in the memory 22.

In a fourth phase 14 (i.e., Phase 4) of the test process 30, the first logic state is read in the first cell (represented by “R1”) in the first clock cycle 34 and/or the second clock cycle 36. Nothing new is written to the cells 32 in the fourth phase 14 of the test process 30. Therefore, the write port and write address corresponding to the first clock cycle 34 are each denoted with an “X.”

Still referring to FIG. 4, the logic states used in the fifth through eighth phases 14 (i.e., Phases 5-8) of the testing process 30 are generally a mirror image or the opposite of the logic states used in the first four phases (i.e., Phases 1-4). In other words, where the logic “1” is written and read in Phases 1-4 in FIG. 4, the logic “0” is written and read in Phases 5- 8. Likewise, where the logic “0” is written and read in Phases 1-4 in FIG. 4, the logic “1” is written and read in Phases 5- 8. As such, each cell 32 or bit of the memory 22 (e.g., SRAM) is tested using both the logic “1” and the logic “0” for the both read and the write operations.

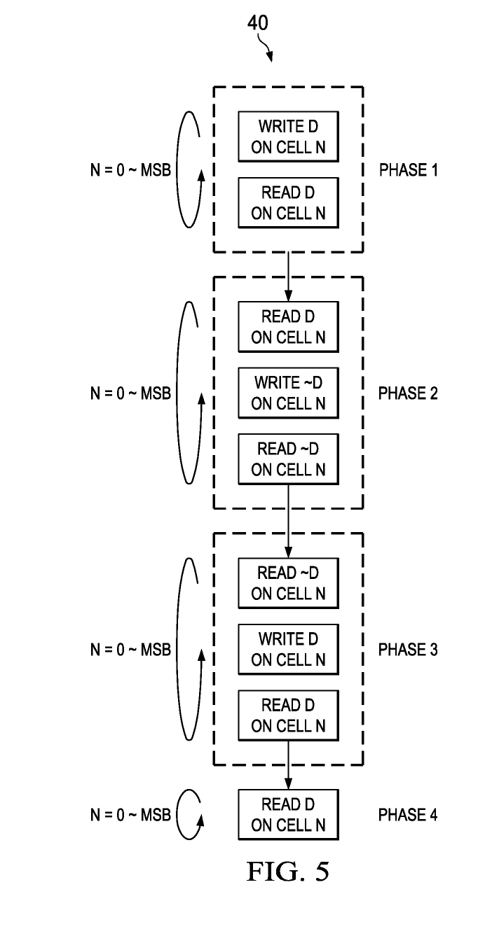

Moving now to FIG. 5, a flow diagram 40 corresponding to the conventional or typical testing process 10 of FIG. 1 using three clock cycles is provided. As shown in FIG. 5, in Phase 1 a write operation is performed to give a first cell (“N”) a first logic state (“D”) and a read operation is performed to read the first logic state on the first cell. This process is repeated for each of the cells (as represented by “N=0˜MSB”).

In Phase 2, a read operation is performed to read the first logic state on the first cell, a write operation is performed to give a first cell a second logic state (“˜D”), and a read operation is performed to read the second logic state on the first cell. This process is repeated for each of the cells (as represented by “N=0˜MSB”). In Phase 3, a read operation is performed to read the second logic state on the first cell, a write operation is performed to give a first cell a first logic state, and a read operation is performed to read the first logic state on the first cell. This process is repeated for each of the cells (as represented by “N=0˜MSB”).

Finally, in Phase 4 a read operation is performed to read the first logic state on the first cell. This process is repeated for each of the cells (as represented by “N=0˜MSB”). While not shown in FIG. 4, it should be appreciated that the process continues for phases 5-8 using swapped logic states as shown in FIG. 1.

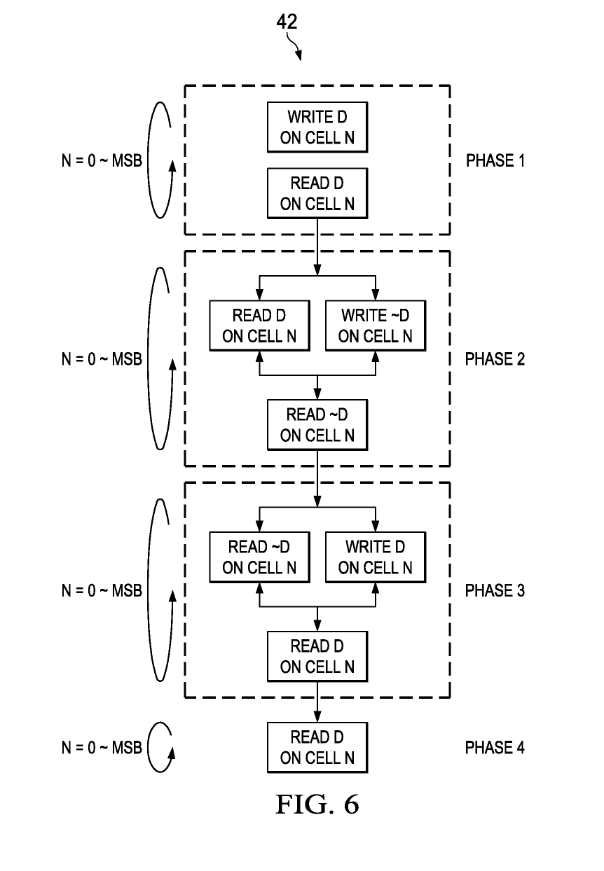

Moving now to FIG. 6, a flow diagram 42 corresponding to the embodiment testing process 30 of FIG. 4 using only two clock cycles is provided. As shown in FIG. 6, in Phase 1 a write operation is performed to give a first cell (“N”) a first logic state (“D”) and a read operation is performed to read the first logic state on the first cell. This process is repeated for each of the cells (as represented by “N=0˜MSB”).

In Phase 2, a read operation is performed to read the first logic state on the first cell and a write operation is concurrently performed to give a first cell a second logic state (“˜D”). Thereafter, a read operation is performed to read the second logic state on the first cell. This process is repeated for each of the cells (as represented by “N=0˜MSB”). In Phase 3, a read operation is performed to read the second logic state on the first cell and a write operation is concurrently performed to give a first cell a first logic state. Thereafter, a read operation is performed to read the first logic state on the first cell. This process is repeated for each of the cells (as represented by “N=0˜MSB”).

In Phase 4, a read operation is performed to read the first logic state on the first cell. This process is repeated for each of the cells (as represented by “N=0˜MSB”). While not shown in FIG. 4, it should be appreciated that the test process 30 continues for Phases 5-8 using swapped logic states (see FIG. 4). In other words, the logic “1” is used in place of the logic “0” and the logic “0” is used in place of the logic “1” for Phases 5-8 as the test process 30 continues.

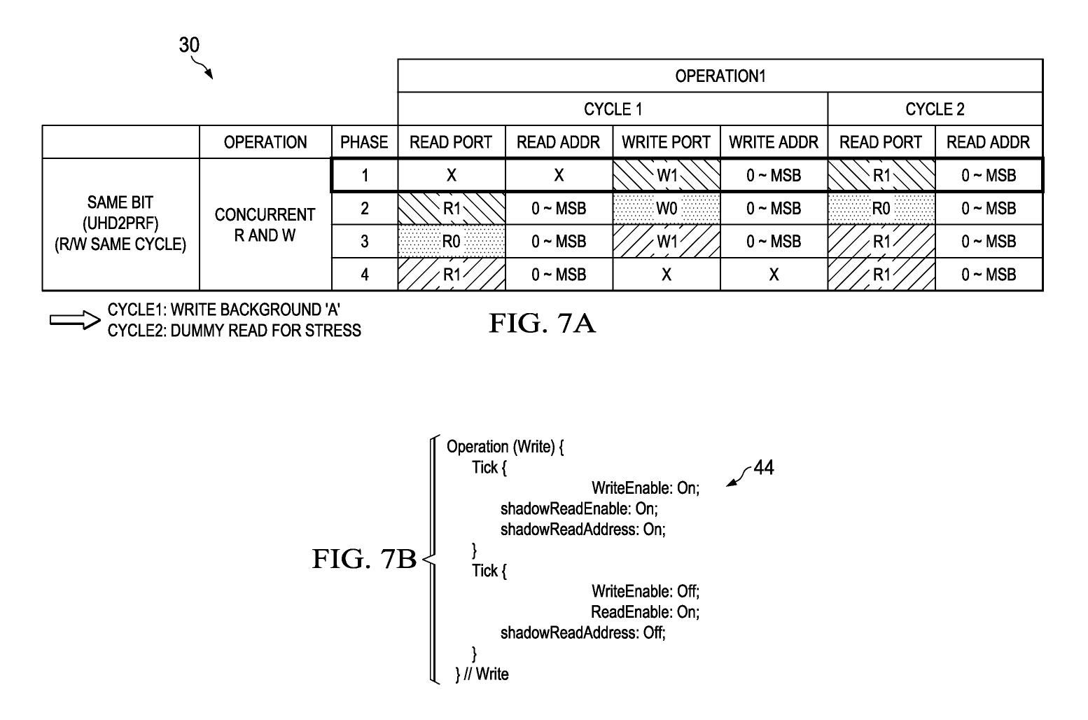

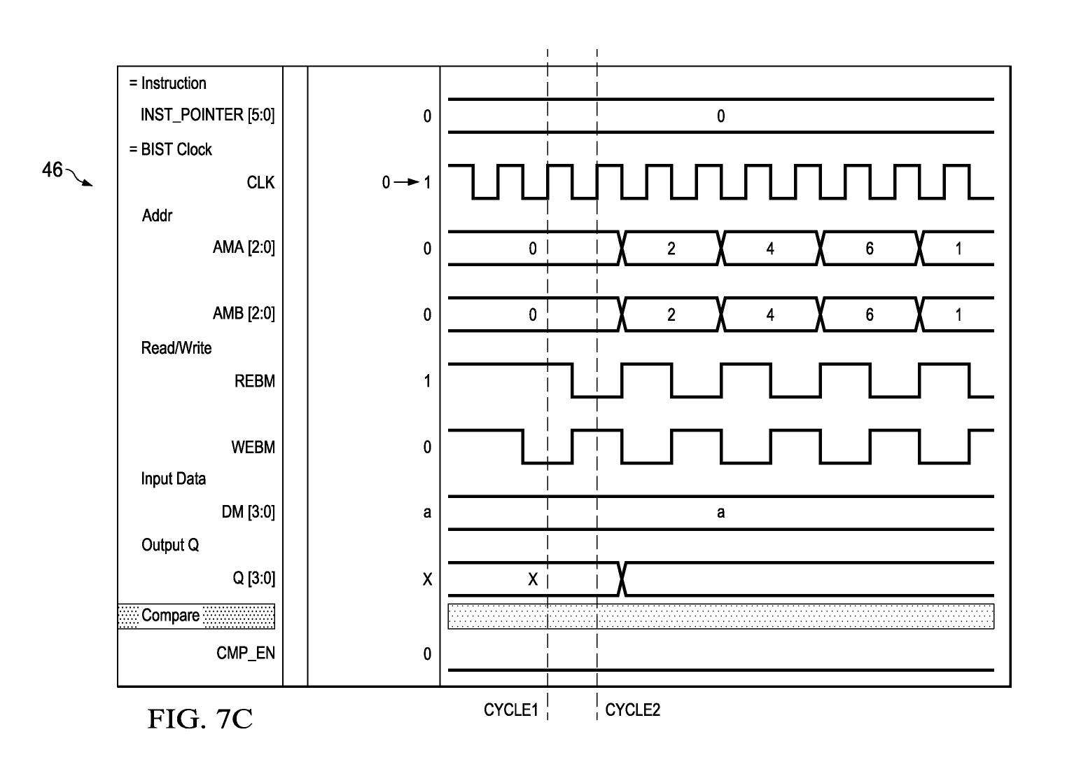

FIGS. 7a-7c collectively illustrate Phase 1 for the embodiment test process 30 of FIG. 4 and FIG. 6. FIG. 7a highlights the read and the write operations that occur during clock cycle 1 and clock cycle 2 during Phase 1 of the test process 30. FIG. 7b illustrates an embodiment algorithm 44 or code that may be used to implement Phase 1. FIG. 7c illustrates a timing diagram 46 highlighting the first clock cycle and the second clock cycle in Phase 1.

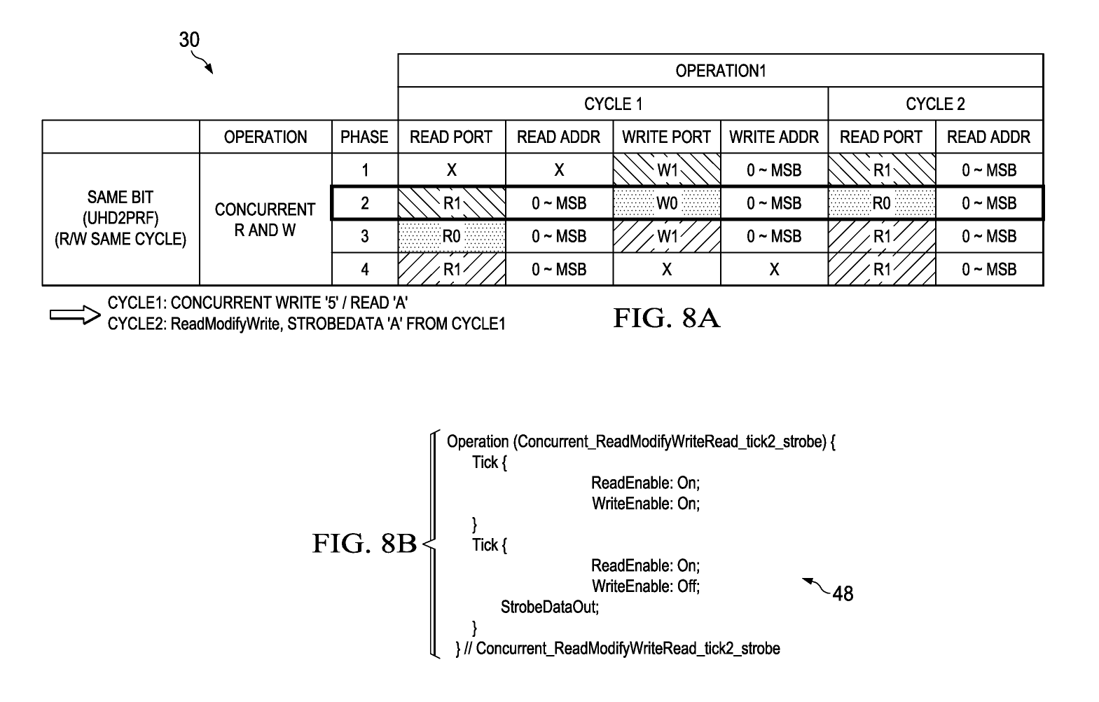

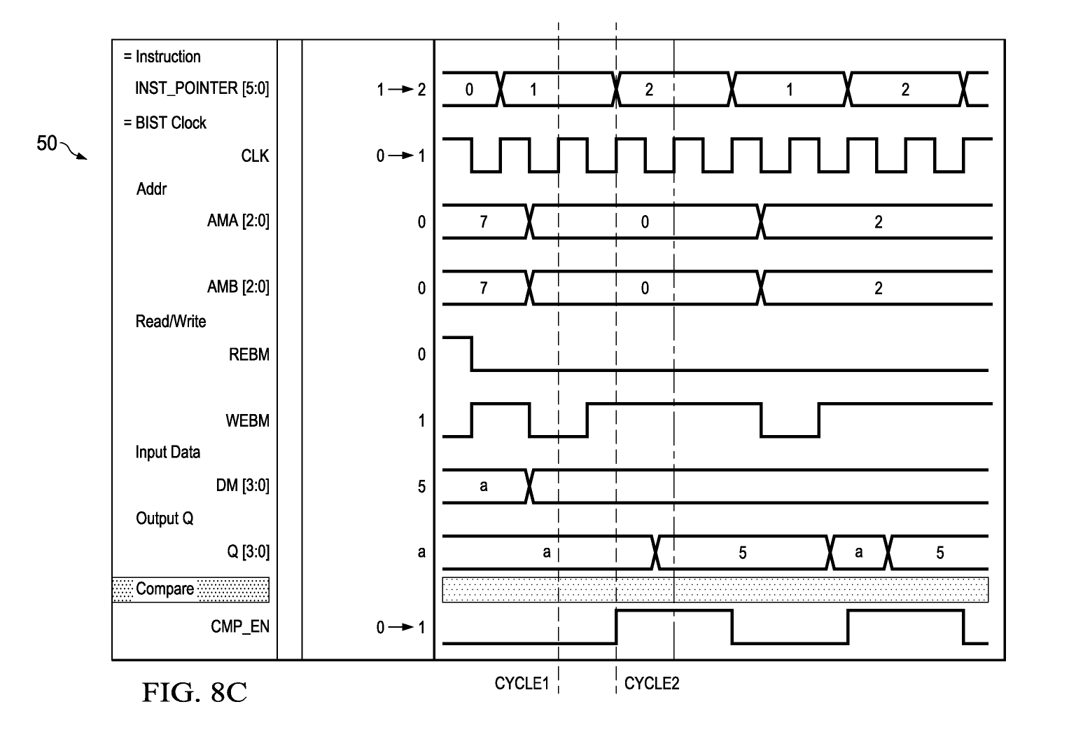

FIGS. 8a-8c collectively illustrate Phase 2 for the embodiment test process 30 of

FIG. 4 and FIG. 6. FIG. 8a highlights the read and the write operations that occur during clock cycle 1 and clock cycle 2 during Phase 2. FIG. 8b illustrates an embodiment algorithm 48 or code that may be used to implement Phase 2. FIG. 8c illustrates a timing diagram 50 highlighting the first cycle and the second cycle in Phase 2.

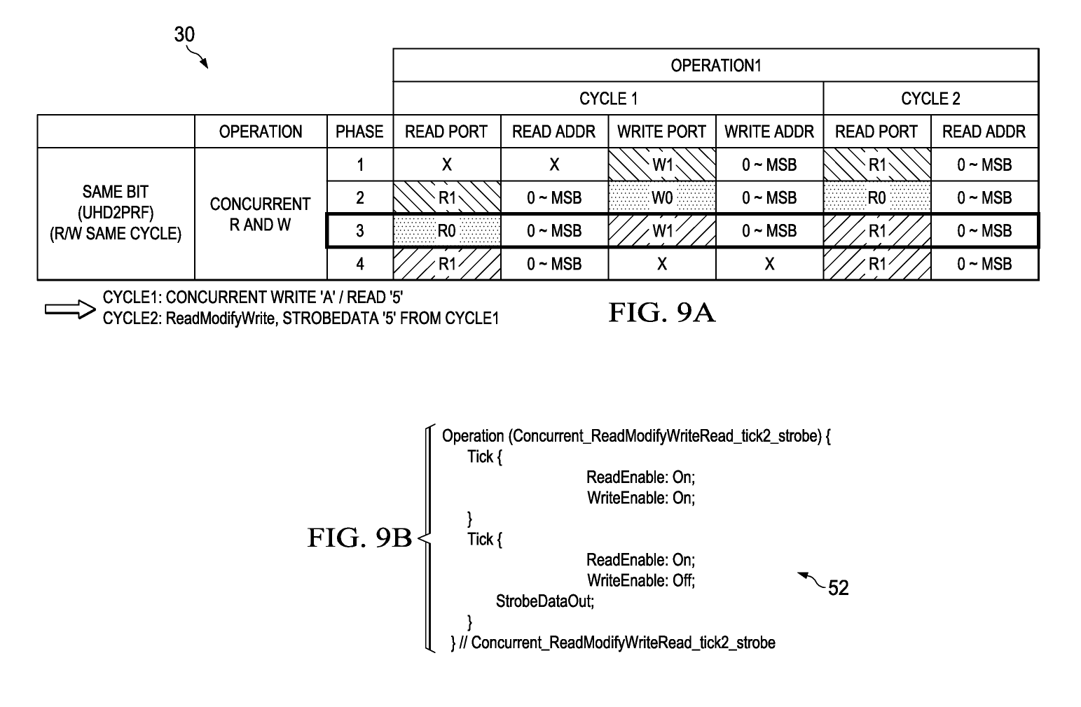

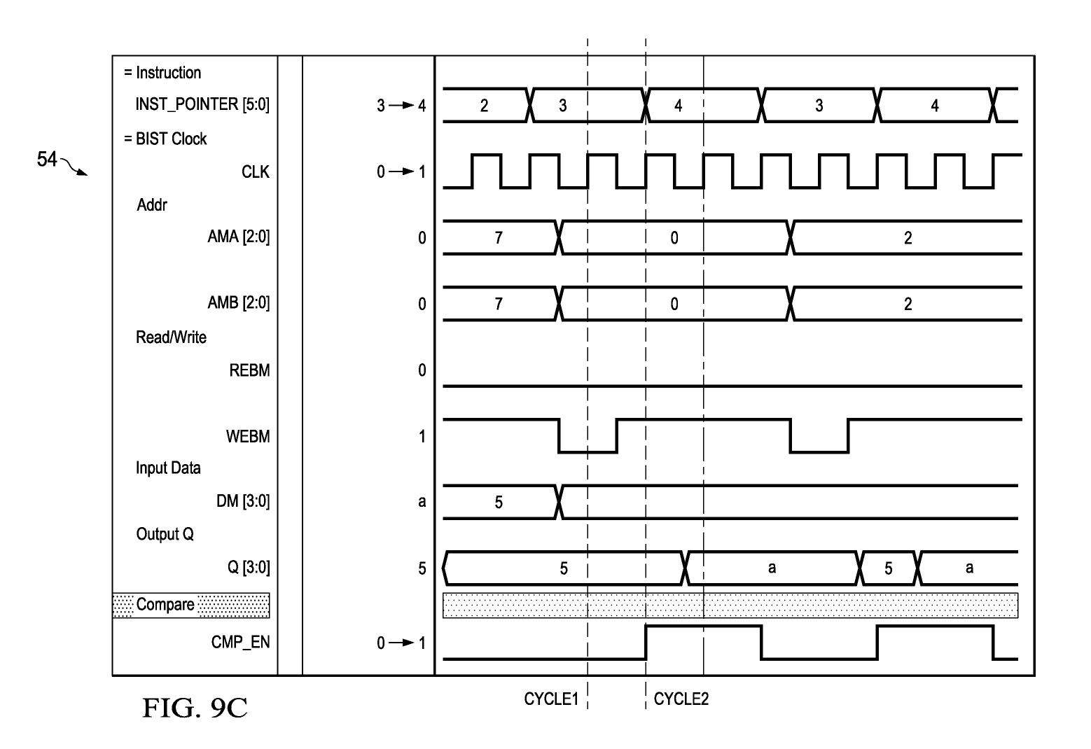

FIGS. 9a-9c collectively illustrate Phase 3 for the embodiment test process 30 of FIG. 4 and FIG. 6. FIG. 9a highlights the read and the write operations that occur during clock cycle 1 and clock cycle 2 during Phase 3. FIG. 9b illustrates an embodiment algorithm 52 or code that may be used to implement Phase 3. FIG. 9c illustrates a timing diagram 54 highlighting the first cycle and the second cycle in Phase 3.

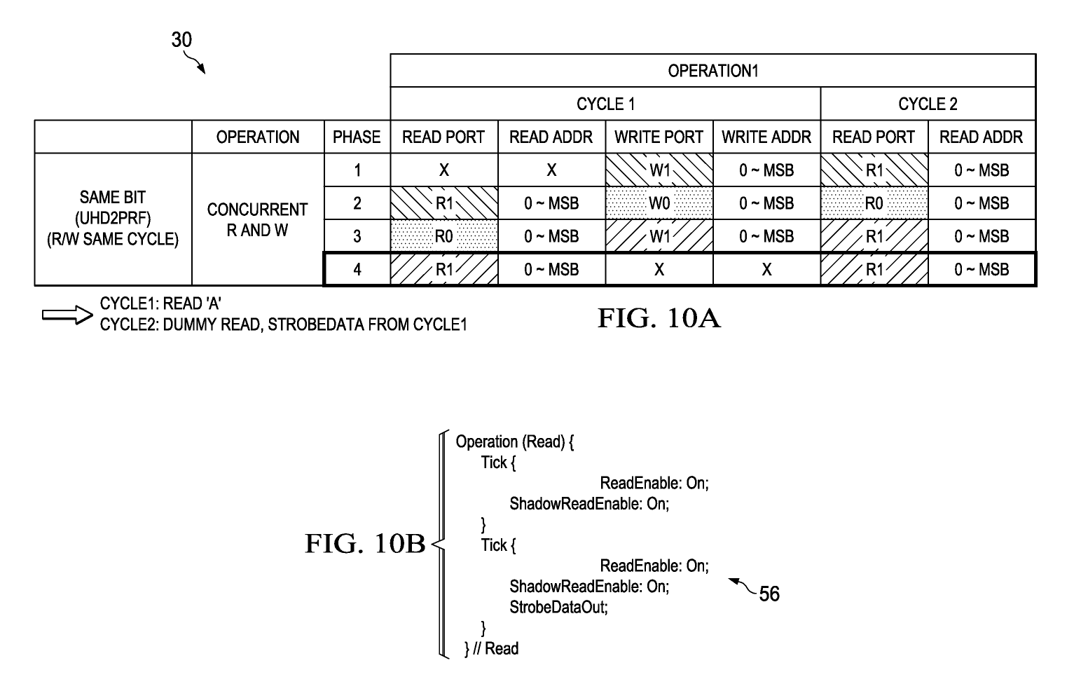

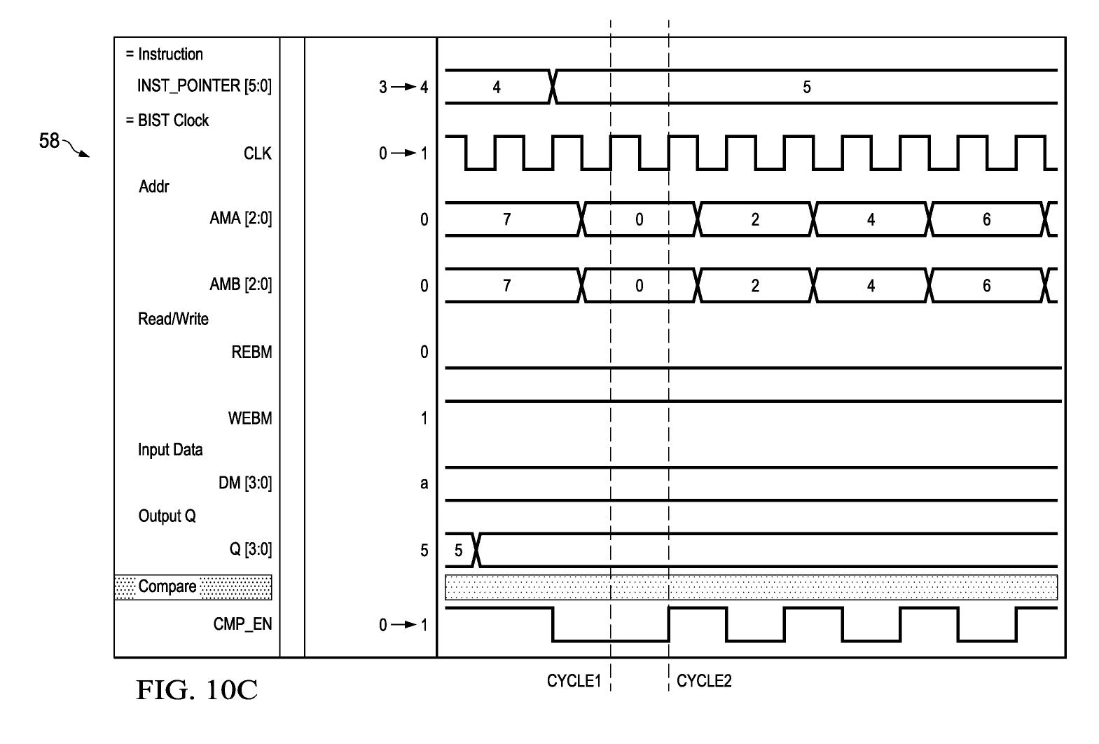

FIGS. 10a-10c collectively illustrate Phase 4 for the embodiment test process 30 of FIG. 4 and FIG. 6. FIG. 10a highlights the read operations that occur during clock cycle 1 and clock cycle 2 during Phase 4. FIG. 10b illustrates an embodiment algorithm 56 or code that may be used to implement Phase 4. FIG. 10c illustrates a timing diagram 58 highlighting the first cycle and the second cycle Phase 4.

The embodiment test process 30 permits the detection of a wide variety of possible faults in cells 32 of the memory (e.g., SRAM). For example, the embodiment test process 30 is able to detect multi-port specific faults such as, for example, bit line shorts and word-line shorts, port interference, and inter-port bit-line coupling. In addition, the embodiment test process 30 is able to detect stuck-at cell faults, transition faults, unlinked dynamic coupling faults, address decoder faults, read/write logic faults, parametric faults, destructive read faults, write recovery faults, leakage faults leading to insufficient data retention, and so on.

In addition to the embodiment test process 30 provides more efficient and higher coverage test methodology for the 2-port register file concurrent read/write, especially when detecting and comparing the read data. In addition, the built-in test mechanism 12 can dramatically improve testing time as it can be embedded into the BIST tool instead of traditional test engineer manual work. Moreover, the failures that are introduced by concurrent read/write can be detected in an earlier stage using the test mechanism 24 and the embodiment test process 30.

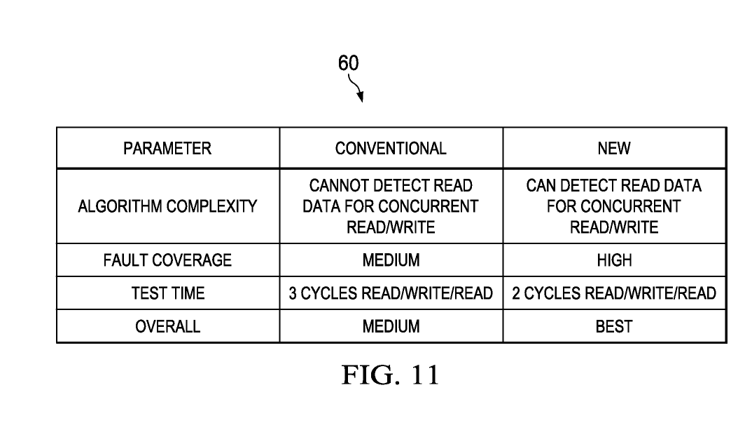

Referring now to FIG. 11, a chart 60 comparing parameters of the typical test process 10 of FIG. 1 with the embodiment testing process of FIG. 4 is provided. As shown, the conventional process 10 cannot detect read data for a concurrent read/write. In contrast, the embodiment test process 30 is able to detect read data for a concurrent read/write. In addition, the fault coverage for the conventional test process 10 is less than that of the embodiment test process 30. Further, the test time of the conventional test process 10 relies on three clock cycles for the read/write/read operations while the embodiment test process 30 is able to operate with only two clock cycles for the read/write/read operations by concurrently reading and writing during, for example, the first clock cycle. As such, when an overall comparison is made, the embodiment test process 30 is superior to the conventional test process 10.

An embodiment method of testing a memory includes writing a first logic state to a first cell in a first clock cycle and reading the first logic state in the first cell in a second clock cycle in a first phase, and reading the first logic state in the first cell and writing a second logic state to the first cell in the first clock cycle and reading the second logic state in the first cell in the second clock cycle in a second phase.

An embodiment method of testing a memory having a plurality of cells including writing a first logic state and reading the first logic state for each of the cells of the memory using only two clock cycles in a first phase, and reading the first logic state, writing a second logic state, and reading the second logic state for each of the cells of the memory using only the two clock cycles in a second phase.

An embodiment integrated circuit includes a static random access memory (SRAM), and a built-in self-test (BIST) component operably coupled to the SRAM, the BIST component operable to: write a first logic state to a first cell of the SRAM in a first clock cycle and to read the first logic state in the first cell of the SRAM in a second clock cycle in a first phase, and read the first logic state in the first cell of the SRAM and to write a second logic state to the first cell of the SRAM in the first clock cycle and to read the second logic state in the first cell of the SRAM in the second clock cycle in a second phase.

While the disclosure provides illustrative embodiments, this description is not intended to be construed in a limiting sense. Various modifications and combinations of the illustrative embodiments, as well as other embodiments, will be apparent to persons skilled in the art upon reference to the description. It is therefore intended that the appended claims encompass any such modifications or embodiments.

What is claimed is:

1. A method of testing a memory, comprising:
writing a first logic state to a first cell in a first clock cycle and reading the first logic state in the first cell in a second clock cycle in a first phase; and
reading the first logic state in the first cell and writing a second logic state to the first cell in the first clock cycle and reading the second logic state in the first cell in the second clock cycle in a second phase.

2. The method of claim 1, further comprising reading the second logic state in the first cell and writing the first logic state to the first cell in the first clock cycle and reading the first logic state in the first cell in the second clock cycle in a third phase.

3. The method of claim 2, further comprising reading the first logic state in the first cell in the first clock cycle and the second clock cycle in a fourth phase.

4. The method of claim 3, further comprising repeating each of the writing steps and each of the reading steps in sequence for a second cell, a third cell, and a fourth cell.

5. The method of claim 3, further comprising writing the second logic state to the first cell in the first clock cycle and reading the second logic state in the first cell in the second clock cycle in a fifth phase and reading the second logic state in the first cell and writing the first logic state to the first cell in the first clock cycle and reading the first logic state in the first cell in the second clock cycle in a sixth phase.

6. The method of claim 5, further comprising reading the first logic state in the first cell and writing the second logic state to the first cell in the first clock cycle and reading the second logic state in the first cell in the second clock cycle in a seventh phase and reading the second logic state in the first cell in the first clock cycle and the second clock cycle in a eighth.

7. The method of claim 1, further comprising writing the first logic state to a second cell, to a third cell, and to a fourth cell in the first clock cycle and reading the first logic state in the second cell, the third cell, and the fourth cell in the second clock cycle in the first phase.

8. The method of claim 7, further comprising reading the first logic state in the second cell, the third cell, and the fourth cell and writing the second logic state to the second cell, the third cell, and the fourth cell in the first clock cycle and reading the second logic state in the second cell, the third cell, and the fourth cell in the second clock cycle in the second phase.

9. The method of claim 1, wherein the first cell is disposed in a static random access memory (SRAM).

10. The method of claim 9, wherein the SRAM is a multiple transistor, two-port register file SRAM.

11. The method of claim 1, wherein the reading steps and the writing steps are performed without using a third clock cycle in the first phase and the second phase.

12. The method of claim 1, wherein the first logic state is a one and the second logic state is a zero.

13. A method of testing a memory having a plurality of cells, comprising:
writing a first logic state and reading the first logic state for each of the cells of the memory using only two clock cycles in a first phase; and
reading the first logic state, writing a second logic state, and reading the second logic state for each of the cells of the memory using only the two clock cycles in a second phase.

14. The method of claim 13, further comprising reading the second logic state, writing the first logic state, and reading the first logic state for each of the cells of the memory using only the two clock cycles in a third phase and reading the first logic state for each of the cells of the memory in a fourth phase.

15. The method of claim 14, further comprising swapping the first logic state and the second logic state and repeating the writing steps and the reading steps for a fifth phase in place of the first phase, a sixth phase in place of the second phase, a seventh phase in place of the third phase, and an eighth phase in place of the fourth phase.

16. The method of claim 1, wherein each of the cells of the memory are tested in sequence and read and write addresses for the cells are based on a most significant bit.

17. An integrated circuit, comprising:
a static random access memory (SRAM); and
a built-in self-test (BIST) component operably coupled to the SRAM, the BIST component operable to:
write a first logic state to a first cell of the SRAM in a first clock cycle and to read the first logic state in the first cell of the SRAM in a second clock cycle in a first phase; and
read the first logic state in the first cell of the SRAM and to write a second logic state to the first cell of the SRAM in the first clock cycle and to read the second logic state in the first cell of the SRAM in the second clock cycle in a second phase.

18. The integrated circuit of claim 17, wherein the BIST component is operable to test a second cell of the SRAM after the first cell has been written to and read.

19. The integrated circuit of claim 17, wherein the BIST component operates without employing a third clock cycle.

20. The integrated circuit of claim 17, wherein the SRAM is a multiple bit, two-port register file SRAM.
